(19) United States
(12) Patent Application Publication
(10) Pub. No.: US 2018/0122908 A1
(43) Pub. Date: May 3, 2018

(54) SILICON GERMANIUM ALLOY FIN WITH MULTIPLE THRESHOLD VOLTAGES

(71) Applicant: International Business Machines Corporation, Armonk, NY (US)

(72) Inventors: Karthik Balakrishnan, White Plains, NY (US); Kangguo Cheng, Schenectady, NY (US); Pouya Hashemi, White Plains, NY (US); Alexander Reznicek, Troy, NY (US)

(21) Appl. No.: 15/338,789

(22) Filed: Oct. 31, 2016

(51) Int. Cl. H01L 29/10; H01L 29/161; H01L 29/78; H01L 29/06; H01L 29/08; H01L 29/66

(52) U.S. Cl. CPC H01L 29/1054; H01L 29/161; H01L 29/785; H01L 29/66545; H01L 29/0847; H01L 29/1083; H01L 29/66795; H01L 29/0649

(57) ABSTRACT

A semiconductor structure is provided that includes a strained silicon germanium alloy fin structure and a relaxed silicon germanium alloy fin structure located in different device regions of a substrate. The relaxed silicon germanium alloy fin provides a higher threshold voltage than the strained silicon germanium alloy fin structure.

### BACKGROUND

The present application relates to a semiconductor structure and a method of forming the same. More particularly, the present application relates to a semiconductor structure that includes a strained silicon germanium alloy fin structure and a relaxed silicon germanium alloy fin structure located in different device regions of a substrate, wherein the relaxed silicon germanium alloy fin structure provides a higher threshold voltage than the strained silicon germanium alloy fin structure. A method of forming such a semiconductor structure is also provided.

For more than three decades, the continued miniaturization of metal oxide semiconductor field effect transistors (MOSFETs) has driven the worldwide semiconductor industry. Various showstoppers to continued scaling have been predicated for decades, but a history of innovation has sustained Moore's Law in spite of many challenges. However, there are growing signs today that metal oxide semiconductor transistors are beginning to reach their traditional scaling limits. Since it has become increasingly difficult to improve MOSFETs and therefore complementary metal oxide semiconductor (CMOS) performance through continued scaling, further methods for improving performance in addition to scaling have become critical.

The use of non-planar semiconductor devices such as, for example, silicon fin field effect transistors (FinFETs) is the next step in the evolution of complementary metal oxide semiconductor (CMOS) devices. Silicon fin field effect transistors (FETs) can achieve better device characteristics as compared to conventional planar FETs. In order to extend these devices for multiple technology nodes such as, for example, 10 nm and beyond, there is a need to boost the performance with high-mobility channels.

In such FinFET devices, a fin containing a silicon germanium alloy is one promising channel material because of its high-carrier mobility. Strained silicon germanium alloy fins are viable for pFET performance enhancement. Multiple threshold voltage devices are needed for such semiconductor structures.

### SUMMARY

A semiconductor structure is provided that includes a strained silicon germanium alloy fin structure and a relaxed silicon germanium alloy fin structure located in different device regions of a substrate. The relaxed silicon germanium alloy fin structure provides a higher threshold voltage than the strained silicon germanium alloy fin structure.

In one aspect of the present application, a semiconductor structure containing multiple threshold voltage silicon germanium alloy fins is provided. In one embodiment, the semiconductor structure includes a strained silicon germanium alloy fin structure located in one device region of a substrate, and a relaxed silicon germanium alloy fin structure located in another device region of the substrate. A first functional gate structure straddles over a portion of the strained silicon germanium alloy fin structure, and a second functional gate structure straddles over a portion of the relaxed silicon germanium alloy fin structure. A first source/drain structure is located on each side of the first functional gate structure and is present on sidewall surfaces and a topmost surface of the strained silicon germanium alloy fin structure. A second source/drain structure is located on each side of the second functional gate structure and is present only on sidewall surfaces of the relaxed silicon germanium alloy fin structure.

In another aspect of the present application, a method of forming a semiconductor structure containing multiple threshold voltage silicon germanium alloy fins is provided. In one embodiment, the method includes providing a silicon germanium alloy fin extending upward from a surface of a substrate, the silicon germanium alloy fin being strained. An isolation structure is then formed entirely through the silicon germanium alloy fin to provide a first strained silicon germanium alloy fin structure in a first device region and a second strained silicon germanium alloy fin structure in a second device region. Next, a first gate structure is formed straddling over a portion of the first strained silicon germanium alloy fin structure and a second gate structure is formed straddling over a portion of the second strained silicon germanium alloy fin structure. A block mask is formed over the first device region. Exposed portions of the second strained silicon germanium alloy fin structure are then removed utilizing the second gate structure as an etch mask, wherein the remaining portion of the second strained silicon germanium alloy fin structure provides a relaxed silicon germanium alloy fin structure. Next, the block mask is removed from the first device region. A first source/drain structure is formed on sidewall surfaces and a topmost surface of the first strained silicon germanium alloy fin structure and on each side of the first gate structure, and a second source/drain structure is formed on sidewall surfaces of the relaxed silicon germanium alloy fin structure and on each side of the second gate structure.

The method of the present application provides a way to tune the device threshold voltage for the same germanium content silicon germanium alloy fin structures having different strain values. The body doping and functional gate stack structures can be identical thereby reducing the process burden for different threshold voltage devices. No additional topography is introduced by utilizing the method of the present application.

### BRIEF DESCRIPTION OF SEVERAL VIEWS OF THE DRAWINGS

FIG. 1A is a cross sectional view of an exemplary semiconductor structure including, from bottom to top, a base semiconductor substrate, a punch through stop layer, and a silicon germanium alloy fin (this cross sectional view is along a length-wise direction of the silicon germanium alloy fin).

FIG. 1B is a cross sectional view through B-B′ of the exemplary semiconductor structure of FIG. 1 (this cross sectional view is along a width-wise direction of the silicon germanium alloy fin).

FIG. 2 is a cross sectional view of the exemplary semiconductor structure of FIGS. 1A-1B after forming an isolation structure entirely through the silicon germanium alloy fin to provide a first strained silicon germanium alloy fin structure in a first device region and a second strained silicon germanium alloy fin structure in a second device region (this cross sectional view is along a length-wise direction of the silicon germanium alloy fin).

FIG. 3 is a cross sectional view of the exemplary semiconductor structure of FIG. 2 after forming a first gate structure straddling over a portion of the first strained silicon germanium alloy fin structure and a second gate structure straddling over a portion of the second strained silicon germanium alloy fin structure.

FIG. 4 is a cross sectional view of the exemplary semiconductor structure of FIG. 3 after forming a block mask over the first device region.

FIG. 5 is a cross sectional view of the exemplary semiconductor structure of FIG. 4 after performing an etch to remove exposed portions of the second strained silicon germanium alloy fin structure utilizing the second gate structure as an etch mask, wherein the remaining portion of the second strained silicon germanium alloy fin structure provides a relaxed silicon germanium alloy fin structure.

FIG. 6 is a cross sectional view of the exemplary semiconductor structure of FIG. 5 after removing the block mask from the first device region.

FIG. 7A is a cross sectional view of the exemplary semiconductor structure of FIG. 6 after forming a first source/drain structure on surfaces of the first strained silicon germanium alloy fin structure and on each side of the first gate structure, and a second source/drain structure on surfaces of the remaining portion of the second strained silicon germanium alloy fin structure and on each side of the second gate structure.

FIG. 7B is a cross sectional view through B-B′ of the exemplary semiconductor structure of FIG. 7A.

FIG. 7C is a cross sectional view through C-C′ of the exemplary semiconductor structure of FIG. 7A.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

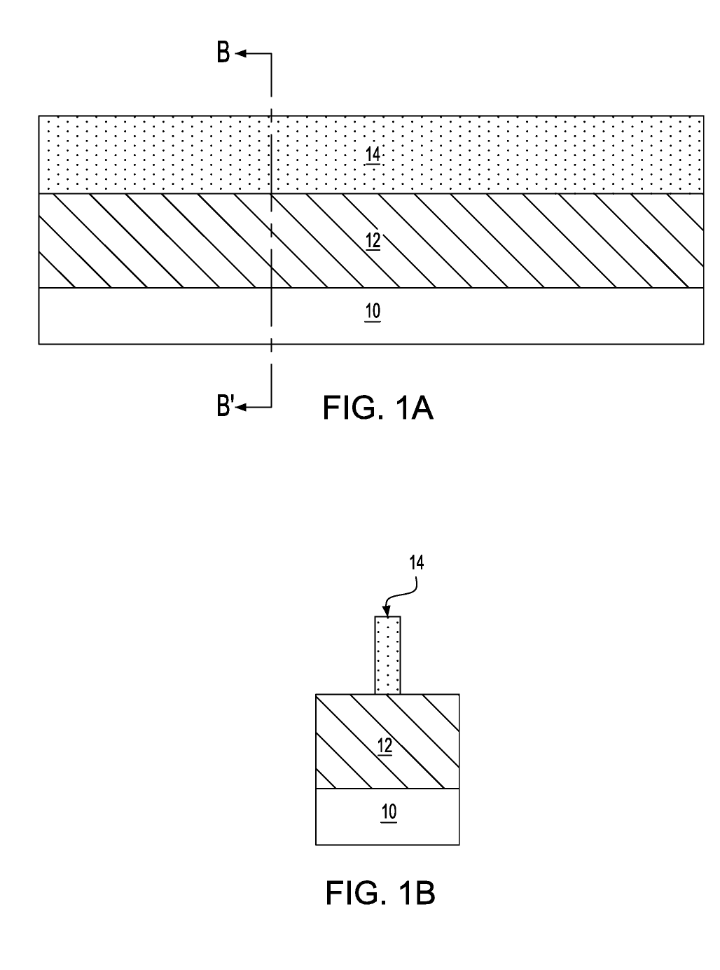

Referring first to FIGS. 1A-1B, there are shown various cross sectional views (along a length-wise direction of the silicon germanium alloy fin 14, and a width-wise direction of the silicon germanium alloy fin 14, respectively) of an exemplary semiconductor structure that can be employed in accordance with one embodiment of the present application. The exemplary semiconductor structure shown in FIGS. 1A-1B includes, from bottom to top, a base semiconductor substrate 10, a punch through stop layer 12, and a silicon germanium alloy fin 14. In some embodiments, the punch through stop layer 12 is omitted. The base semiconductor substrate 10 alone, or in combination with the punch through stop layer 12 may be referred to as a substrate. The silicon germanium alloy fin 14 thus extends upward from a topmost surface of the substrate.

The base semiconductor substrate 10 may include at least one semiconductor material having semiconducting properties. Examples of semiconductor materials that may provide at least a portion of the base semiconductor substrate 10 may include silicon (Si), germanium (Ge), silicon germanium alloys (SiGe), silicon carbide (SiC), silicon germanium carbide (SiGeC), III-V compound semiconductors or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In one embodiment, the base semiconductor substrate 10 is a bulk semiconductor substrate. By “bulk” it is meant that the semiconductor substrate is entirely composed of at least one semiconductor material, as defined above. In one example, the base semiconductor substrate 10 may be entirely composed of silicon. In some embodiments, the bulk semiconductor substrate may include a multilayered semiconductor material stack including at least two different semiconductor materials, as defined above.

In another embodiment, the base semiconductor substrate 10 may comprise a topmost semiconductor material layer of a semiconductor-on-insulator (SOI) substrate. The top semiconductor material layer of the SOI substrate may include one of the semiconductor materials mentioned above. In one example, the topmost semiconductor material layer of the SOI substrate may be composed of silicon. The SOI substrate would also include, from bottom to top, an optional handle substrate (not shown) and an insulator layer (not shown). The handle substrate may include one of the above mentioned semiconductor materials or a non-semiconductor material such as a dielectric material or a conductive material. The insulator layer may include a buried oxide and/or a buried nitride.

In any of the above embodiments, the semiconductor material that provides the base semiconductor substrate 10 may be a single crystalline semiconductor material. The semiconductor material that provides the base semiconductor substrate 10 may have any of the well known crystal orientations. For example, the crystal orientation of the base semiconductor substrate 10 may be {100}, {110}, or {111}. Other crystallographic orientations besides those specifically mentioned can also be used in the present application.

The punch through stop layer 12, which is continuously present on the entirety of the base semiconductor substrate 10, is composed of a first semiconductor material of a first conductivity type. In some embodiments, the punch through stop layer 12 may be omitted. The first semiconductor material that provides the punch through stop layer 12 may include one of the semiconductor materials mentioned above for providing the base semiconductor substrate 10. In one embodiment, the first semiconductor material that provides the punch through stop layer 12 may comprise a same semiconductor material as the base semiconductor substrate 10. For example, the base semiconductor substrate 10 and the first semiconductor material that provides the punch through stop layer 12 may be composed of silicon. In yet another embodiment, the first semiconductor material that provides the punch through stop layer 12 may comprise a different semiconductor material than the base semiconductor substrate 10. For example, the base semiconductor substrate 10 may be composed of silicon, while the first semiconductor material that provides the punch through stop layer 12 may be composed of germanium.

The first conductivity type of the first semiconductor material that provides the punch through stop layer 12 may be provided by a p-type or n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous.

In one embodiment of the present application, the concentration of n-type or p-type dopant within the first semiconductor material that provides the punch through stop layer 12 can range from 1×10¹⁸ atoms/cm³ to 1×10²¹ atoms/cm³, although dopant concentrations greater than 1×10²¹ atoms/cm³ or less than 1×10¹⁸ atoms/cm³ are also conceived. In one embodiment, the doping within the first semiconductor material that provides the punch through stop layer 12 may be uniform (i.e., have a uniform distribution of dopants throughout the entire region). In another embodiment, the doping within the first semiconductor material that provides the punch through stop layer 12 may be graded.

In one embodiment of the present application, the punch through stop layer 12 may have a thickness from 20 nm to 100 nm. Other thicknesses that are lesser than, or greater than, the aforementioned thickness range may also be employed as the thickness of the punch through stop layer 12.

The silicon germanium alloy fin 14 is a strained silicon germanium alloy. Thus, and in embodiments in which the punch though stop layer 12 is present, the punch through stop layer 12 must be composed of a compositional different semiconductor material than the silicon germanium alloy that provides the silicon germanium alloy fin 14. In one example, the punch through stop layer 12 is composed of silicon. In embodiments in which the punch though stop layer 12 is not present, the base semiconductor substrate 10 must be composed of a compositional different semiconductor material than the silicon germanium alloy that provides the silicon germanium alloy fin 14. In one example, the base semiconductor substrate 10 is composed of silicon.

The term “silicon germanium alloy fin” refers to a silicon germanium alloy material that includes a pair of vertical sidewalls that are parallel to each other. As used herein, a surface is “vertical” if there exists a vertical plane from which the surface does not deviate by more than three times the root mean square roughness of the surface. Although a single silicon germanium alloy fin 14 is described and illustrated, a plurality of silicon germanium alloy fins 14 can be formed. In one embodiment of the present application, each silicon germanium alloy fin 14 has a height from 20 nm to 200 nm, and a width from 5 nm to 30 nm. Other heights and/or widths that are lesser than, or greater than, the ranges mentioned herein can also be used in the present application. When multiple silicon germanium alloy fins are present, each silicon germanium alloy fin 14 is spaced apart from its nearest neighboring silicon germanium alloy fin 14 by a pitch of from 20 nm to 100 nm. Also, each silicon germanium alloy fin 14 is oriented parallel to each other.

Each silicon germanium alloy fin 14 may be non-doped or doped. When doped, each silicon germanium alloy fin 14 is of a second conductivity type that is opposite from the first conductivity type. When doped, the n-type or p-type dopant that may be present in each silicon germanium alloy fin 14 is less than the dopant present in the underlying punch through stop layer 12. In one example, the n-type or p-type dopant may be present in each silicon germanium alloy fin 14 in an amount of from 1×10¹⁸ atoms/cm³ to 1×10¹⁹ atoms/cm³.

In one embodiment of the present application, each silicon germanium alloy fin 14 that is present may have a germanium content of from 15 atomic percent germanium to 35 atomic percent germanium. Other germanium contents that are less than 15 atomic percent and greater than 35 atomic percent may also be used in the present application. Each silicon germanium alloy fin 14 that is present has an initial strain value. The initial strain value of each silicon germanium alloy fin 14 may be from 0.5% to 1.5%.

The exemplary semiconductor structure shown in FIGS. 1A-1B may be provided by first providing a material stack of the base semiconductor substrate 10, if present, the punch through stop layer 12 and a layer of a silicon germanium alloy (not shown). After providing such a material stack, the layer of silicon germanium alloy is patterned forming each silicon germanium alloy fin 14.

In one embodiment of the present application, the base semiconductor substrate 10, the punch through stop layer 12, and the layer of silicon germanium alloy (not shown) of the material stack are formed by first providing the base semiconductor substrate 10. An epitaxial growth (or deposition) process may then be employed to form the punch through stop layer 12 and the layer of silicon germanium alloy.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. Since an epitaxial growth process is used in providing the punch through stop layer 12 and the layer of silicon germanium alloy that provide the material stack, the punch through stop layer 12 and the layer of silicon germanium alloy have an epitaxial relationship with each other as well with the base semiconductor substrate 10.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 500° C. to 900° C. Although higher temperature typically results in faster deposition, the faster deposition may result in crystal defects and film cracking. The epitaxial growth of the punch through stop layer 12 and the layer of silicon germanium alloy can be performed utilizing any well known precursor gas or gas mixture. Carrier gases like hydrogen, nitrogen, helium and argon can be used. In some embodiments, a dopant that provides the specific conductivity type to the punch through stop layer 12 and the layer of silicon germanium alloy may be introduced in-situ into the precursor gas or gas mixture that provides the first semiconductor material that provides the punch through stop layer 12 and the layer of silicon germanium alloy that provides each silicon germanium alloy fin 14. In another embodiment, a dopant that provides the specific conductivity type may be introduced into an intrinsic first semiconductor material or an intrinsic silicon germanium alloy by ion implantation or gas phase doping.

In another embodiment of the present application, the base semiconductor substrate 10, the punch through stop layer 12 and the layer of silicon germanium alloy are formed by first providing the base semiconductor substrate 10. Dopants that provide the specific conductivity type of the first semiconductor material that provides the punch through stop layer 12 may then be introduced into base semiconductor substrate 10 by ion implantation or gas phase doping. The layer of silicon germanium alloy can then be epitaxially grown on the punch through stop layer 12.

In another embodiment of the present application, the base semiconductor substrate 10, the punch through stop layer 12 and the layer of silicon germanium alloy can be formed utilizing a wafer bonding process.

After providing the base semiconductor substrate 10, the optional punch through stop layer 12 and the layer of the silicon germanium alloy, a patterning process is used to provide each silicon germanium alloy fin 14.

In one embodiment, patterning may include lithography and etching. The lithographic process includes forming a photoresist (not shown) atop a material or material stack to be patterned, exposing the photoresist to a desired pattern of radiation and developing the exposed photoresist utilizing a conventional resist developer. The photoresist may be a positive-tone photoresist, a negative-tone photoresist or a hybrid-tone photoresist. The photoresist may be formed utilizing a deposition process such as, for example, spin-on coating. The etching process includes a dry etching process (such as, for example, reactive ion etching, ion beam etching, plasma etching or laser ablation), and/or a wet chemical etching process. Typically, reactive ion etching is used in providing the silicon germanium alloy fin 14.

In another embodiment, patterning may include a sidewall image transfer (SIT) process. The SIT process includes forming a mandrel material layer (not shown) atop the material or material layers that are to be patterned. The mandrel material layer (not shown) can include any material (semiconductor, dielectric or conductive) that can be selectively removed from the structure during a subsequently performed etching process. In one embodiment, the mandrel material layer (not shown) may be composed of amorphous silicon or polysilicon. In another embodiment, the mandrel material layer (not shown) may be composed of a metal such as, for example, Al, W, or Cu. The mandrel material layer (not shown) can be formed, for example, by chemical vapor deposition or plasma enhanced chemical vapor deposition. Following deposition of the mandrel material layer (not shown), the mandrel material layer (not shown) can be patterned by lithography and etching to form a plurality of mandrel structures (also not shown) on the topmost surface of the structure.

The SIT process continues by forming a spacer (not shown) on each sidewall of each mandrel structure. The spacer can be formed by deposition of a spacer material and then etching the deposited spacer material. The spacer material may comprise any material having an etch selectivity that differs from the mandrel material. Examples of deposition processes that can be used in providing the spacer material include, for example, chemical vapor deposition (CVD), plasma enhanced chemical vapor deposition (PECVD), or atomic layer deposition (ALD). Examples of etching that be used in providing the spacers include any etching process such as, for example, reactive ion etching.

After formation of the spacers, the SIT process continues by removing each mandrel structure. Each mandrel structure can be removed by an etching process that is selective for removing the mandrel material. Following the mandrel structure removal, the SIT process continues by transferring the pattern provided by the spacers into the underlying material or material layers. The pattern transfer may be achieved by utilizing at least one etching process. Examples of etching processes that can used to transfer the pattern may include dry etching (i.e., reactive ion etching, plasma etching, and ion beam etching or laser ablation) and/or a chemical wet etch process. In one example, the etch process used to transfer the pattern may include one or more reactive ion etching steps. Upon completion of the pattern transfer, the SIT process concludes by removing the spacers from the structure. Each spacer may be removed by etching or a planarization process.

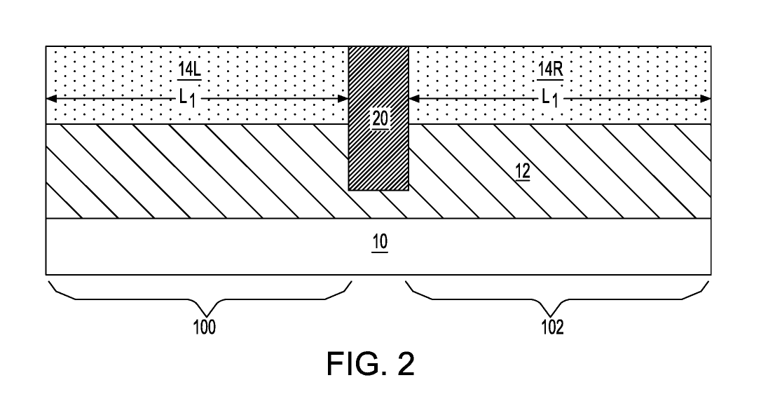

Referring now to FIG. 2, there is illustrated the exemplary semiconductor structure of FIGS. 1A-1B after forming an isolation structure 20 entirely through the silicon germanium alloy fin 14 to provide a first strained silicon germanium alloy fin structure 14L in a first device region 100 and a second strained silicon germanium alloy fin structure 14R in a second device region 102. Although one first strained silicon germanium alloy fin structure 14L and one second strained silicon germanium fin structure 14R are described and illustrated, a plurality of first and/or second strained silicon germanium alloy fin structures can be formed. The first device region 100 is a region of the substrate in which a first type of semiconductor device can be subsequently formed, while the second device region 102 is a region of the substrate in which a second type of semiconductor device, different from the first type of semiconductor device, is subsequently formed.

In some embodiments, and as is shown, the isolation structure 20 extends beneath the bottommost surface of the first strained silicon germanium alloy fin structure 14L and a bottommost surface of the second strained silicon germanium alloy fin structure 14R. In such an embodiment, the isolation structure 20 has a bottommost surface that stops within a sub-surface of the underlying substrate. By “sub-surface portion” it is meant a surface of a material that is located between the topmost surface of the material and a bottommost surface of the material. In the illustrated embodiment, the isolation structure 20 has a bottommost surface that stops within a sub-surface of the punch through stop layer 12. The isolation structure 20 can be formed by forming a trench (by lithography and etching) and then filling the trench with a trench dielectric material such as, for example, silicon dioxide. An etch back process may follow the trench fill. In one embodiment, the isolation structure 20 has a topmost surface that is coplanar with a topmost surface of the first strained silicon germanium alloy fin structure 14L and a topmost surface of the second strained silicon germanium alloy fin structure 14R. Alternatively, the topmost surface of isolation structure 20 can be lower than the topmost surface of first and second strained silicon germanium alloy fin structures 14L, 14R.

The first strained silicon germanium alloy fin structure 14L and the second strained silicon germanium alloy fin structure 14R constitute remaining portions of the silicon germanium alloy fin 14 that are not removed during formation of the isolation structure 20. Thus, the first strained silicon germanium alloy fin structure 14L and the second strained silicon germanium alloy fin structure 14R each have a germanium content that is the same as the silicon germanium alloy fin 14.

The first strained silicon germanium alloy fin structure 14L and the second strained silicon germanium alloy fin structure 14R have a first length, L₁, that is less than the initial length of the silicon germanium alloy fin 14. In one example, the first length, L₁, of the first strained silicon germanium alloy fin structure 14L and the second strained silicon germanium alloy fin structure 14R is from 100 nm to 2000 nm. As is shown, the topmost surface and the bottommost surface of the first strained silicon germanium alloy fin structure 14L are coplanar with a topmost surface and a bottommost surface, respectively, of the second strained silicon germanium alloy fin structure 14R.

The first strained silicon germanium alloy fin structure 14L and the second strained silicon germanium alloy fin structure 14R have a first strain that may be the same as, or slightly less than, the initial strain value of the silicon germanium alloy fin 14. In the present application, the formation of the isolation structure 20 may facilitate slight relaxation of the resultant fin structures 14L, 14R. In one example, the first strain value of the first strained silicon germanium alloy fin structure 14L and the second strained silicon germanium alloy fin structure 14R may be from 0.5% to 1.5%.

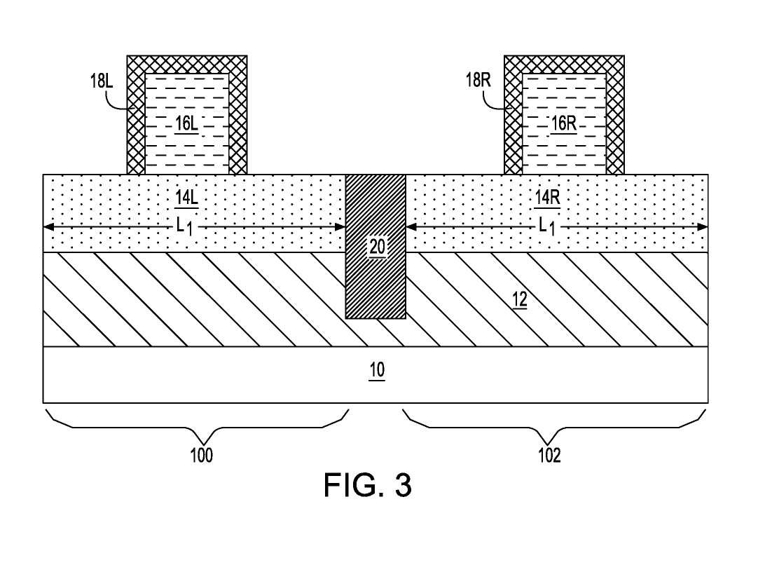

Referring to FIG. 3, there is illustrated the exemplary semiconductor structure of FIG. 2 after forming a first gate structure 16L straddling over a portion of the first strained silicon germanium alloy fin structure 14L and a second gate structure 16R straddling over a portion of the second strained silicon germanium alloy fin structure 14R. Although a single first gate structure 16L and a single second gate structure 16R are described and illustrated, a plurality of first gate structures 16L and/or second gate structures 16R may be formed. Each gate structure 16L, 16R lies perpendicular to the strained silicon germanium alloy fin structures 14L, 14R and is orientated parallel to another gate structure. By “straddling over” it is meant one material (i.e., the first and second gate structures 16L, 16R) are present on sidewalls and a topmost surface of another material (i.e., the strained silicon germanium alloy fin structures 14L, 14R).

In some embodiments, a first gate spacer 18L can be present on the exposed sidewalls and, optionally, the topmost surface of the first gate structure 16L and a second gate spacer 18R may be present on the exposed sidewalls and, optionally, the topmost surface of the second gate structure 16R.

In one embodiment, the first and second gate structures 16L, 16R both include functional gate structures or sacrificial gate structures. In yet another embodiment, at least one of the gate structures is a functional gate structure, while the other gate structure is a sacrificial gate structure. The term “functional gate structure” denotes a permanent gate structure that is used to control output current (i.e., flow of carriers in the channel) of a semiconducting device through electrical or magnetic fields. The term “sacrificial gate structure” denotes a material or material stack that server as a placeholder for a subsequently formed functional gate structure.

When a functional gate structure is used as the first gate structure and/or the second gate structure, each functional gate structure may include a gate material stack (not shown) of from bottom to top, a gate dielectric portion, and a gate conductor portion. In some embodiments, the gate material stack may also include a gate cap portion.

The gate dielectric portion may include a gate dielectric material. The gate dielectric material that provides the gate dielectric portion can be an oxide, nitride, and/or oxynitride. In one example, the gate dielectric material that provides the gate dielectric portion can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high-k gate dielectric, can be formed and used as the gate dielectric portion. In some embodiments, a first set of functional gate structures includes a first gate dielectric portion, while a second set of functional gate structures comprises a second gate dielectric portion. In such an embodiment, the first gate dielectric material portion may be the same as, or different from, the second gate dielectric material portion.

The gate dielectric material used in providing the gate dielectric portion can be formed by any deposition process including, for example, chemical vapor deposition (CVD), plasma enhanced chemical vapor deposition (PECVD), physical vapor deposition (PVD), sputtering, or atomic layer deposition. In some embodiments and when different gate dielectric materials are used in providing the gate dielectric portions of different functional gate structures, block mask technology can be used. In one embodiment of the present application, the gate dielectric material used in providing the gate dielectric portion can have a thickness in a range from 1 nm to 10 nm. Other thicknesses that are lesser than, or greater than, the aforementioned thickness range can also be employed for the gate dielectric material that may provide the gate dielectric portion.

The gate conductor portion can include a gate conductor material. The gate conductor material used in providing the gate conductor portion can include any conductive material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide) or multilayered combinations thereof. In some embodiments, a first set of functional gate structures includes a first gate conductor portion, while a second set of functional gate structures comprises a second gate conductor portion. In such an embodiment, the first gate conductor portion may be the same as, or different from, the second gate conductor portion. For example, the first gate conductor portion may comprise an nFET gate metal, while the second gate conductor portion may comprise a pFET gate metal. In another example, the first gate conductor portion may comprise a pFET gate metal, while the second gate conductor portion may comprise an nFET gate metal.

The gate conductor material used in providing the gate conductor portion can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes. When a metal silicide is formed, a conventional silicidation process is employed. When a different gate conductor material is used for gate conductor portions of different functional gate structures, block mask technology can be used. In one embodiment, the gate conductor material used in providing the gate conductor portion has a thickness from 20 nm to 150 nm. Other thicknesses that are lesser than, or greater than, the aforementioned thickness range can also be employed for the gate conductor material used in providing the gate conductor portion.

If present, gate cap portion of the functional gate structure may include a gate cap material. The gate cap material that provides the gate cap portion may include a hard mask material such as, for example, silicon dioxide, silicon nitride, and/or silicon oxynitride. When a plurality of functional gate structures are formed, the hard mask material of a first gate gap portion of a first set of functional gate structure may be the same as, or different from, the hard mask material of a second gate gap portion of a second set of functional gate structures. The hard mask material that provides the gate cap portion can be formed utilizing a conventional deposition process such as, for example, chemical vapor deposition or plasma enhanced chemical vapor deposition. The material that provides the gate cap portion can have a thickness from 5 nm to 20 nm. Other thicknesses that are lesser than, or greater than, the aforementioned thickness range can also be employed as the thickness of the material that provides the gate cap portion.

Each functional gate structure can be formed by providing a functional gate material stack of, from bottom to top, the gate dielectric material, the gate conductor material and, if present, the gate cap material. A patterning process may follow the formation of the functional gate material stack. Block mask technology may be used to selectively provide one of the functional gate structures prior to forming the other functional gate structure.

Next, a gate spacer (i.e., the first and second gate spacers 18L, 18R) can be formed on surfaces of each gate structure (i.e., the first and second gate structures 16L, 16R). The gate spacer (i.e., the first and second gate spacers 18L, 18R) may include any gate dielectric spacer material such as, for example, silicon dioxide and/or silicon nitride. The gate spacer (i.e., the first and second gate spacers 18L, 18R) can be formed by deposition of a gate dielectric spacer material and thereafter etching the deposited gate dielectric spacer material. In some embodiments, the gate spacer material may be removed from atop the topmost surface of each gate structure.

In other embodiments, at least one, preferably, both, the first and second gate structures (16L, 16R) are sacrificial gate structures. When a sacrificial gate structure is employed, the sacrificial gate structure is replaced with a functional gate structure after forming the source/drain structures. In such an embodiment, the gate dielectric portion of the functional gate structure that replaces the sacrificial gate structure may be U-shaped. By “U-shaped” it is meant a material that includes a bottom horizontal portion and a sidewall portion that extends upward from each end of the bottom horizontal portion. When employed, each sacrificial gate structure may include a sacrificial gate dielectric portion, a sacrificial gate material portion and a sacrificial gate cap portion. In some embodiments, each sacrificial gate dielectric portion and/or each sacrificial gate cap portion may be omitted. Each sacrificial gate dielectric portion includes one of the dielectric materials mentioned above for gate dielectric portion. Each sacrificial gate material portion includes one of the gate conductor materials mentioned above for the gate conductor portion. The sacrificial gate cap portion includes one of the gate cap materials mentioned above for the gate cap portion. The sacrificial gate structure can be formed by deposition of the various material layers and then patterning the resultant sacrificial dielectric material sack by utilizing, for example, lithography and etching. Next, a gate spacer (i.e., the first and second gate spacers 18L, 18R) as mentioned above can be formed on the exposed surfaces of each gate structure.

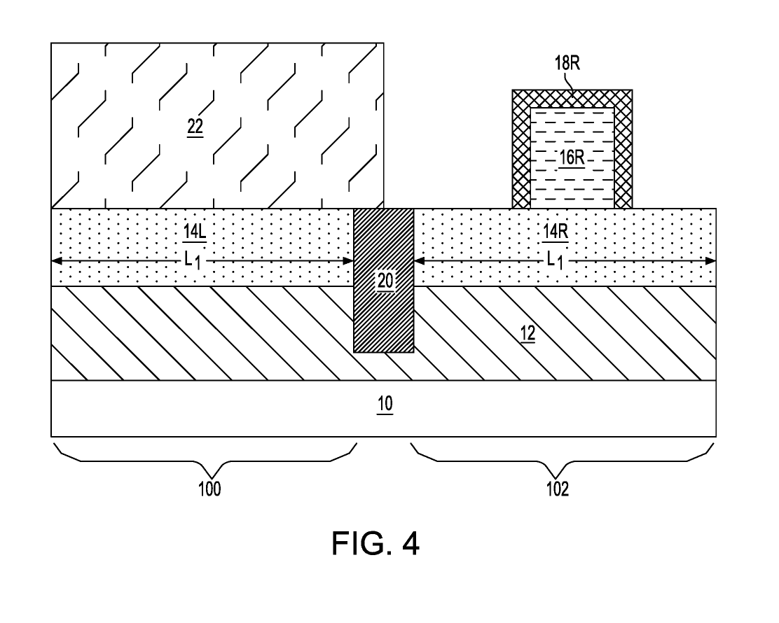

Referring now to FIG. 4, there is illustrated the exemplary semiconductor structure of FIG. 3 after forming a block mask 22 over the first device region 100. Although the present application describes and illustrates the formation of block mask 22 over the first device region 100, the block mask 22 may be formed over the second device region 102. Block mask 22 may include any block mask material such as, for example, silicon dioxide, silicon nitride, silicon oxynitride, a photoresist material or any combination thereof. The block mask may be formed by deposition of the block mask material followed by patterning the block mask material. Patterning may include lithography only, or a combination of lithography and etching may be used in providing the block mask 22. In some embodiments, and as shown, the block mask 22 may extend onto the topmost surface of the isolation structure 20.

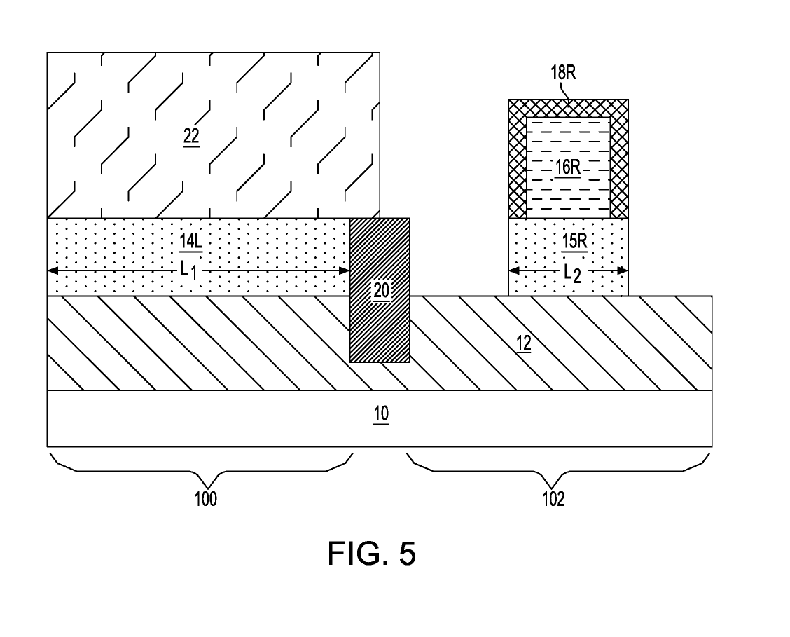

Referring now to FIG. 5, there is illustrated the exemplary semiconductor structure of FIG. 4 after performing an etch to remove (i.e., recess) exposed portions of the second strained silicon germanium alloy fin structure 14R utilizing the second gate structure 16R and optionally the second gate spacer 18R as an etch mask, wherein the remaining portion of the second strained silicon germanium alloy fin structure 14R has a second strain value that is less than the first strain value. The remaining portion of the second strained silicon germanium alloy fin structure 14R that has the second strain value may be referred to herein as a relaxed silicon germanium alloy fin structure 15R; the remaining first strained silicon germanium alloy fin structure 14L may be referred to simply as the strained silicon germanium alloy fin structure. The relaxed silicon germanium alloy fin structure 15R has sidewalls that are vertically aligned to the outer sidewalls of the etch mask i.e., the second gate spacer 18R, and the second gate structure 16R). Thus, the relaxed silicon germanium alloy fin structure 15R is located entirely beneath the etch mask (i.e., the second gate spacer 18R, and the second gate structure 16R).

The etch used to provide the relaxed silicon germanium alloy fin structure 15R may include an isotropic etch such as, for example, reactive ion etching. The removal of the exposed portions of the second strained silicon germanium alloy fin structure 14R relaxes the strain value of the remaining portion of the second strained silicon germanium alloy fin structure 14R.

In one example, the second strain value of the relaxed silicon relaxed silicon germanium alloy fin structure 15R is from 0% to 0.4%. The relaxed silicon germanium alloy fin structure 15R has a same germanium content as the initial silicon germanium alloy fin 14.

The relaxed silicon germanium alloy fin structure 15R has a second length, L₂, that is less than first length, L₁, mentioned above. In one embodiment of the present application, the second length, L₂, is from 15 nm to 50 nm. The relaxed silicon germanium alloy fin structure 15R has a topmost surface and a bottommost surface that are coplanar with a topmost surface and a bottommost surface of the first strained silicon germanium alloy fin structure 14L (each remaining first strained silicon germanium alloy fin structure 14L may be referred to herein as a strained silicon germanium alloy fin structure).

In embodiments in which the block mask 22 is formed over the second device region 102, the first strained silicon germanium alloy fin structure 14L in the first device region 100 can be processed to provide a relaxed silicon germanium alloy fin structure in the first device region 100.

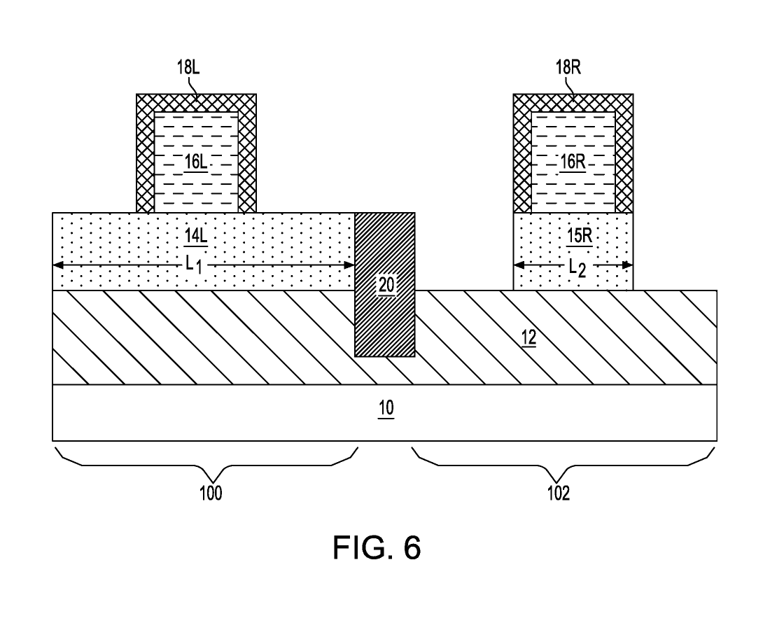

Referring now to FIG. 6, there is illustrated the exemplary semiconductor structure of FIG. 5 after removing the block mask 22 from the first device region 100. The block mask 22 can be removed utilizing any conventional material removal process that is selective in removing the block mask material that provides the block mask 22. In one example, and when the block mask 22 is composed entirely of a photoresist material, the block mask 22 may be removed utilizing an ashing process.

In some embodiments, additional block masks can be formed over desired device regions while other device regions can be processed to relax a preselected number of strained silicon germanium alloy fin structures.

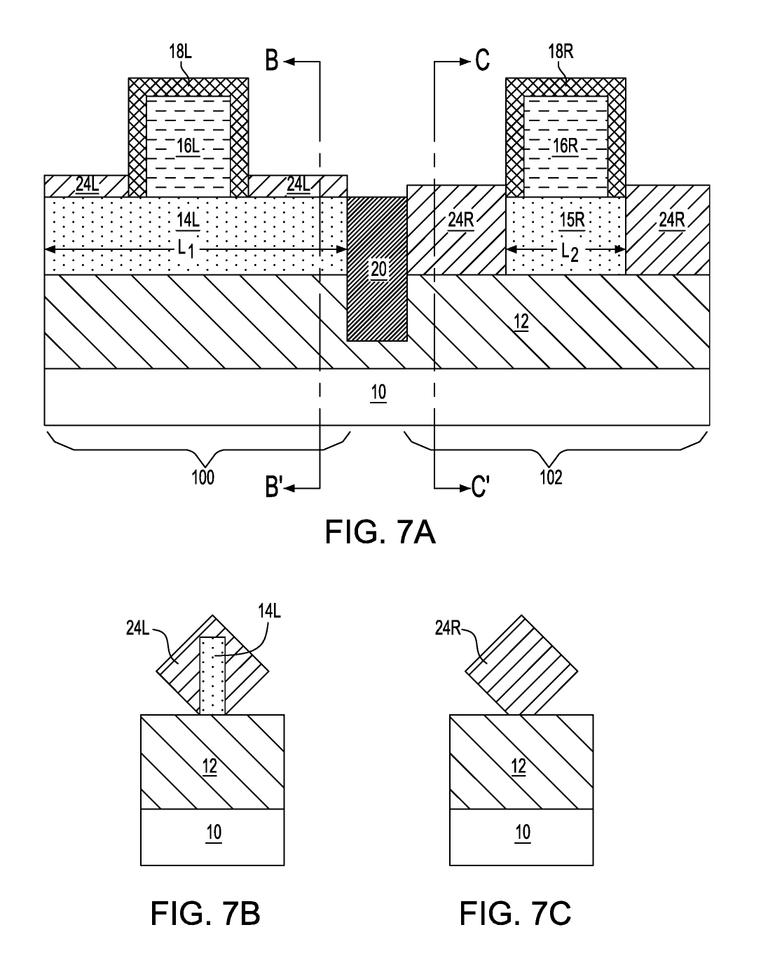

Referring now to FIGS. 7A, 7B and 7C, there are shown various cross sectional views of exemplary semiconductor structure of FIG. 6 after forming a first source/drain structure 24L on surfaces of the first strained silicon germanium alloy fin structure 14L and on each side of the first gate structure 16L, and a second source/drain structure 24R on surfaces of the remaining portion of the second strained silicon germanium alloy fin structure (i.e., relaxed silicon germanium alloy fin structure 15R) and on each side of the second gate structure 16.

The first source/drain structure 24L and the second source/drain structure 24R are formed at the same time utilizing an epitaxial growth process as described above. The first and second source/drain regions 24L, 24R include a semiconductor material and a dopant. In one embodiment, the semiconductor material that provides the first and second source/drain regions 24L, 24R may include a same semiconductor material (i.e., a silicon germanium alloy) as the strained silicon germanium alloy fin structure 14L and the relaxed silicon germanium alloy fin structure 15R. In another embodiment, the semiconductor material that provides the first and second source/drain regions 24L, 24R may include a different semiconductor material than the strained silicon germanium alloy fin structure 14L and the relaxed silicon germanium alloy fin structure 15R. In one example, the semiconductor material that provides the first and second source/drain regions 24L, 24R may be composed of silicon, germanium or a III-V compound semiconductor.

The dopant that is present in the first and second source/drain regions 24L, 24R may be an n-type dopant or a p-type dopant as mentioned above. The dopant may be introduced into the precursor gas or gas mixture used to provide the semiconductor material that provides the first and second source/drain regions 24L, 24R. Alternatively, the dopant may be introduced into an intrinsic semiconductor material utilizing, for example, gas phase doping. The first and second source/drain structures 24R, 24L may have a dopant concentration of from 1×10¹⁹ atoms/cm³ to 2×10²¹ atoms/cm³.

As is shown in FIGS. 7A-7B, the first source/drain structure 24L is present on sidewall surfaces and a topmost surface of the strained silicon germanium alloy fin 14L. The first source/drain structure 24L may be referred to as a cladding source/drain structure. As is shown in FIGS. 7A and 7C, the second source/drain structure 24R is present only on sidewall surfaces of the relaxed silicon germanium alloy fin structure 15R. The second source/drain structure 24L may be referred to as an embedded source/drain structure.

Each of the first and second source/drain structures 24L, 24R has faceted surfaces, i.e., non-planar surfaces. In some embodiments and shown in FIG. 7B, the first source/drain structure 24L is triangular in shape, wherein the base of the triangle directly contacts each of the sidewalls of the strained silicon germanium alloy fin structure 14L and a tip of the triangle extends outward from the sidewalls of the strained silicon germanium alloy fin structure 14L. In some embodiments, and as shown in FIG. 7B, each triangle may merge above the topmost surface of the strained silicon germanium alloy fin structure 14L. In such an instance, the first source/drain structure 24L has a diamond shape. As is shown in FIGS. 7A and 7C, the second source/drain structure 24R that is present only on the sidewalls of the relaxed silicon germanium alloy fin structure 15R has a diamond shape.

The height of each of the first and second source/drain structures 24L, 24R may be substantially the same. By “substantially the same” it is meant that the height of the source/drain structure is within±15 nm from each other.

In the illustrated embodiment, one sidewall of the strained silicon germanium alloy fin structure 14L contacts a first sidewall of the isolation structure 20, while a sidewall of the second source/drain structure 24R contacts a second sidewall of the isolation structure 20.

If sacrificial gate structures are present, the sacrificial gate structures can now be replaced with a functional gate structure utilizing techniques well known to those skilled in the art. For example, the sacrificial gate structures can be replaced by first forming a middle-of-the-line (MOL) dielectric material atop the first and second source/drain structures 24L, 24R and laterally surrounding the strained silicon germanium alloy fin structure 14L and the relaxed silicon germanium alloy fin structure 15R. The MOL dielectric material would have a topmost surface that is coplanar with a topmost surface of the sacrificial gate structure. Each sacrificial gate structure can be removed utilizing an etching process to provide a gate cavity and thereafter a functional gate structure (as defined above) can be formed into each gate cavity. So as not to obscure the method of the present application, the replacement of the sacrificial gate structure is not specifically illustrated in the drawings of the present application.

In accordance with the present application and due to the different strain values of the strained and relaxed silicon germanium alloy fin structures, the semiconductor device that includes the strained silicon germanium alloy fin structure 14L has a first threshold voltage, while the semiconductor device that includes the relaxed silicon germanium alloy fin structure 15R has a second threshold voltage in which the second threshold voltage is greater than the first threshold voltage. In one embodiment, the second threshold voltage may be about 100 meV greater than the first threshold voltage. In one example, the semiconductor device having the first threshold voltage is a logic device such as a pFinFET, while the semiconductor device having the second threshold voltage is a static access memory device.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

1. A semiconductor structure comprising:
a strained silicon germanium alloy fin structure located in one device region of a substrate and a relaxed silicon germanium alloy fin structure located in another device region of the substrate, wherein an entirety of the strained silicon germanium alloy fin structure, as measured from an outermost sidewall to an opposing outermost sidewall, has a first length, and an entirety of the second relaxed silicon germanium alloy fin structure, as measured from an outermost sidewall to an opposing outermost sidewall, has a second length that is less than the first length, wherein the strained silicon germanium alloy fin structure and the relaxed silicon germanium fin structure are located directly on a semiconductor material of the substrate, wherein the semiconductor material of the substrate is selected from at least one of silicon, germanium, a III-V compound semiconductor and a II-VI compound semiconductor;
a first functional gate structure straddling over a portion of the strained silicon germanium alloy fin structure;
a second functional gate structure straddling over a portion of the relaxed silicon germanium alloy fin structure;
a first source/drain structure located on each side of the first functional gate structure and present on sidewall surfaces and a topmost surface of the strained silicon germanium alloy fin structure;
a second source/drain structure located on each side of the second functional gate structure and present only on sidewall surfaces of the relaxed silicon germanium alloy fin structure; and
an isolation structure located in a portion of the substrate and having a topmost surface that is coplanar with a topmost surface of each of the strained silicon germanium alloy fin structure and the relaxed silicon germanium alloy fin structure, the isolation structure separating each device region from one another, and wherein a sidewall of the strained silicon germanium alloy fin structure contacts a first sidewall of the isolation structure and a sidewall of the second source/drain structure contacts a second sidewall of the isolation structure.

2. The semiconductor structure of claim 1, wherein the strained silicon germanium alloy fin structure provides a semiconductor device having a first threshold voltage, and the relaxed silicon germanium alloy fin structure provides a semiconductor device having a second threshold voltage, wherein the second threshold voltage is greater than the first threshold voltage.

3. The semiconductor structure of claim 1, wherein the strained silicon germanium alloy fin structure and the relaxed silicon germanium fin structure have a same germanium content.

4. The semiconductor structure of claim 3, wherein the germanium content is from 15 atomic percent germanium to 35 atomic percent germanium.

5. The semiconductor structure of claim 1, wherein the strained silicon germanium alloy fin structure has a first strain value from 0.5% to 1.5% and the relaxed silicon germanium alloy fin structure has a second stain value from 0% to 0.4%.

6. The semiconductor structure of claim 1, wherein the substrate comprises a punch through stop layer located on a base semiconductor substrate.

7. The semiconductor structure of claim 1, wherein the substrate consists of a base semiconductor substrate.

8.-9. (canceled)

10. The semiconductor structure of claim 1, wherein the first and second source/drain structures are diamond shaped.

11. A method of forming a semiconductor structure, the method comprising:
providing a silicon germanium alloy fin extending upward from a surface of a substrate, the silicon germanium alloy fin being strained and the substrate is composed of a semiconductor material selected from at least one of silicon, germanium, a III-V compound semiconductor and a II-VI compound semiconductor;
forming an isolation structure entirely through the silicon germanium alloy fin to provide a first strained silicon germanium alloy fin structure in a first device region and a second strained silicon germanium alloy fin structure in a second device region;
forming a first gate structure straddling over a portion of the first strained silicon germanium alloy fin structure and a second gate structure straddling over a portion of the second strained silicon germanium alloy fin structure;
forming a block mask over the first device region;
removing an entirety of exposed portions of the second strained silicon germanium alloy fin structure utilizing the second gate structure as an etch mask, wherein the remaining portion of the second strained silicon germanium alloy fin structure provides a relaxed silicon germanium alloy fin structure, wherein the trench isolation structure has a topmost surface that is coplanar with a topmost surface of each of the first strained silicon germanium alloy fin structure and the relaxed silicon germanium alloy fin structure, and wherein an entirety of the strained silicon germanium alloy fin structure, as measured from an outermost sidewall to an opposing outermost sidewall, has a first length, and an entirety of the second relaxed silicon germanium alloy fin structure, as measured from an outermost sidewall to an opposing outermost sidewall, has a second length that is less than the first length, wherein the first strained silicon germanium alloy fin structure and the relaxed silicon germanium fin structure are located directly on the semiconductor material of the substrate;
removing the block mask from the first device region; and
forming a first source/drain structure on sidewall surfaces and a topmost surface of the first strained silicon germanium alloy fin structure and on each side of the first gate structure, and a second source/drain structure on sidewall surfaces of the relaxed silicon germanium alloy fin structure and on each side of the second gate structure, wherein a sidewall of the strained silicon germanium alloy fin structure contacts a first sidewall of the isolation structure and a sidewall of the second source/drain structure contacts a second sidewall of the isolation structure.

12. The method of claim 11, wherein the first strained silicon germanium alloy fin structure provides a semiconductor device having a first threshold voltage, and the relaxed silicon germanium alloy fin structure provides a semiconductor device having a second threshold voltage, wherein the second threshold voltage is greater than the first threshold voltage.

13. The method of claim 11, wherein the providing the silicon germanium alloy fin comprises:
providing a material stack of a base semiconductor substrate and a strained layer of a silicon germanium alloy; and
patterning the strained layer of the silicon germanium alloy.

14. The method of claim 13, wherein the material stack further comprises a punch through stop layer located between the base semiconductor substrate and the strained layer of the silicon germanium alloy.

15. The method of claim 11, wherein the silicon germanium alloy fin, the first and second strained silicon germanium fin structures and the relaxed silicon germanium alloy fin structure comprise a same germanium content.

16. The method of claim 15, wherein the germanium content is from 15 atomic percent germanium to 35 atomic percent germanium.

17. The method of claim 11, wherein the first strained silicon germanium alloy fin structure has a first strain value from 0.5% to 1.5% and the relaxed silicon germanium alloy fin structure has a second stain value from 0% to 0.4%.

18. (canceled)

19. The method of claim 11, wherein the first and second source/drain structures are diamond shaped.

20. The method of claim 11, wherein the first and second gate structures are sacrificial gate structures, and said sacrificial gate structures are replaced with a functional gate structure after the forming of the first and second source/drain structures.

21. (canceled)

22. The semiconductor structure of claim 1, further comprising a gate spacer located at least on sidewall surfaces of the first and second functional gate structures, wherein the strained silicon germanium alloy fin structure extends beyond an outermost sidewall surface of the gate spacer located on the sidewall surfaces of the first functional gate structure, and wherein the sidewalls of the relaxed silicon germanium alloy fin structure are vertically aligned to the outermost sidewall surfaces of the gate spacer located on the sidewall surfaces of the second functional gate structure.

23. A semiconductor structure comprising:
a strained silicon germanium alloy fin structure located in one device region of a substrate and a relaxed silicon germanium alloy fin structure located in another device region of the substrate, wherein an entirety of the strained silicon germanium alloy fin structure, as measured from an outermost sidewall to an opposing outermost sidewall, has a first length, and an entirety of the second relaxed silicon germanium alloy fin structure, as measured from an outermost sidewall to an opposing outermost sidewall, has a second length that is less than the first length, wherein the strained silicon germanium alloy fin structure and the relaxed silicon germanium fin structure are located directly on a semiconductor material of the substrate, wherein the semiconductor material of the substrate is selected from at least one of silicon., germanium, a III-V compound semiconductor and a II-VI compound semiconductor;
a first functional gate structure straddling over a portion of the strained silicon germanium alloy fin structure;
a second functional gate structure straddling over a portion of the relaxed silicon germanium alloy fin structure;
a first source/drain structure located on each side of the first functional gate structure and present on sidewall surfaces and a topmost surface of the strained silicon germanium alloy fin structure;
a second source/drain structure located on each side of the second functional gate structure and present only on sidewall surfaces of the relaxed silicon germanium alloy fin structure; and
a gate spacer located at least on sidewall surfaces and a topmost surface of the first and second functional gate structures, wherein the strained silicon germanium alloy fin structure extends beyond an outermost sidewall surface of the gate spacer located on the sidewall surfaces of the first functional gate structure, and wherein the sidewall surfaces of the relaxed silicon germanium alloy fin structure are vertically aligned to the outermost sidewall surfaces of the gate spacer located on the sidewall surfaces of the second functional gate structure.
